(19) United States
(12) Patent Application Publication
(10) Pub. No.: US 2006/0177952 A1
(43) Pub. Date: Aug. 10, 2006

(54) Process to make nano-structurated components

(76) Inventors: Vito Lambertini, Giaveno(Torino) (IT); Danieie Pullini, Orbassano(Torino) (IT); Nelio Lipira, Fossano(Cuneo) (IT); Mauro Brignone, Orbassano(Torino) (IT); Piemario Repetto, Orbassano(Torino) (IT); Marzia Paderi, Torino (IT); Rossella Monferino, Torino (IT)

Correspondence Address: NIXON & VANDERHYE, PC, 901 NORTH GLEBE ROAD, 11TH FLOOR, ARLINGTON, VA, 22203, US

(21) Appl. No.: 10/546,896

(22) PCT Filed: Mar. 5, 2004
(86) PCT No.: PCT/IB04/00639

§ 371 Date: Aug. 24, 2005

(30) Foreign Application Priority Data
Mar. 6, 2003 (IT) TO2003A000167

(51) Int. Cl. H01L 21/00

(52) U.S. Cl. 438/29

(57) ABSTRACT

In a process to make a nano-structured component, such as a photonic crystal or an emitter (10) which can be led to incandescence through the passage of electric current, at least one layer made of anodized porous alumina (1) is used as sacrificial element for the structuring of at least a part of the component (10).

The present invention relates to a process to make nano-structured components.

Metal components having nanometric surface structures or reliefs, arranged according to specific shapes or geometries, are currently used in some technological fields, such as micro electromechanical systems or MEMS, so as to obtain diffractive optical arrangements, medical devices, microturbines, and so on.

The present invention aims at indicating a new process to make in a simple and economical way nano-structured components, having reliefs, cavities or structures of nano-metric dimensions, in particular for use in the field of photonics, for example in order to manufacture photonic crystals, and the field of light sources, for example in order to manufacture emitters which can be led to incandescence through the passage of electric current.

Said aim is achieved, according to the present invention, by a process to make nano-structured components characterized in that it envisages the use of at least one layer of anodized porous alumina as sacrificial element for the selective structuring of the component.

The use of one or more layer of alumina enables to obtain a plurality of reliefs or cavities in the component of interest, which are arranged according to a predefined geometry.

Preferred characteristics of the process according to the invention are referred to in the appended claims, which are an integral part of the present description.

Further aims, characteristics and advantages of the present invention will be evident from the following detailed description and from the accompanying drawings, provided as a mere illustrative, non-limiting example, in which:

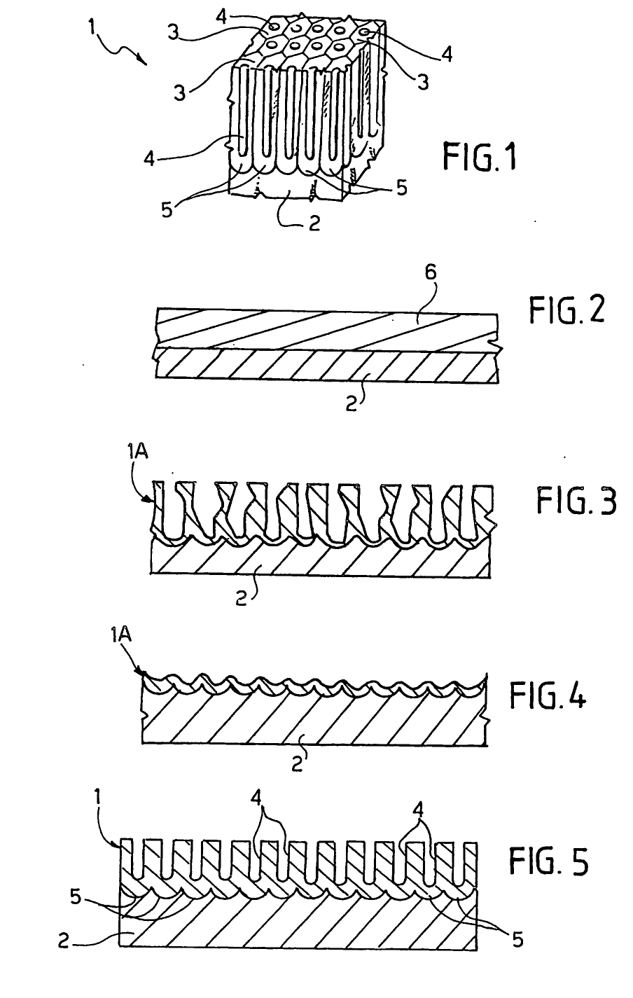

FIG. 1 is a schematic perspective view of a portion of a porous alumina film;

FIGS. 2-5 are schematic views showing some steps of a film-building process for an alumina film as the one shown in FIG. 1;

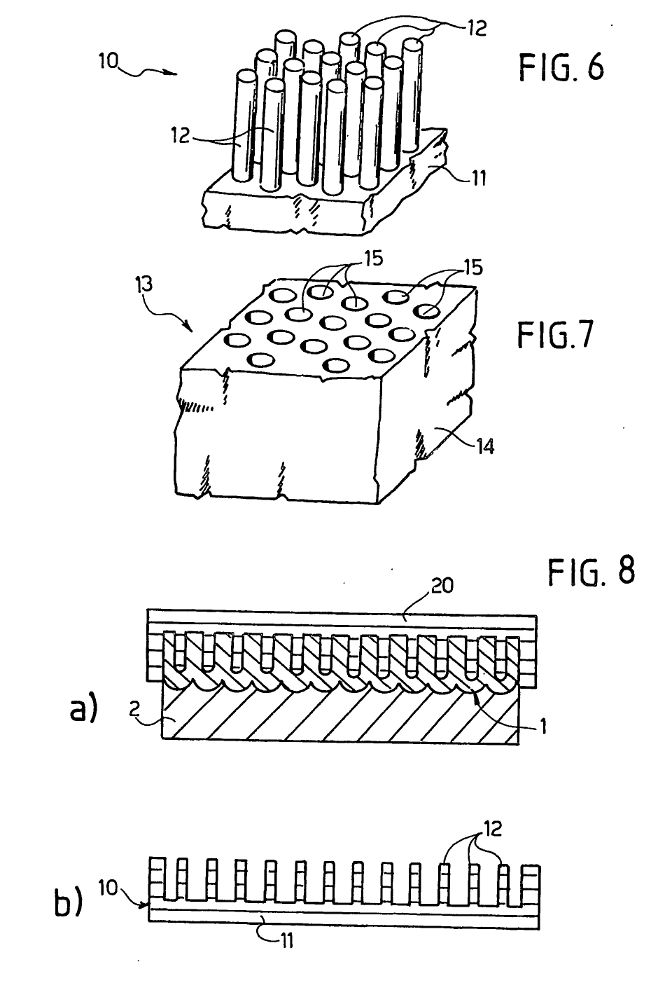

FIG. 6 is a schematic perspective view of a portion of a first nano-structured component as can be made according to the invention;

FIG. 7 is a schematic perspective view of a portion of a second nano-structured component as can be made according to the invention;

FIGS. 8, 9 and 10 are schematic sections showing three different possible implementations of the process according to the invention, as can be used to make a nano-structured component of the type shown in FIG. 6;

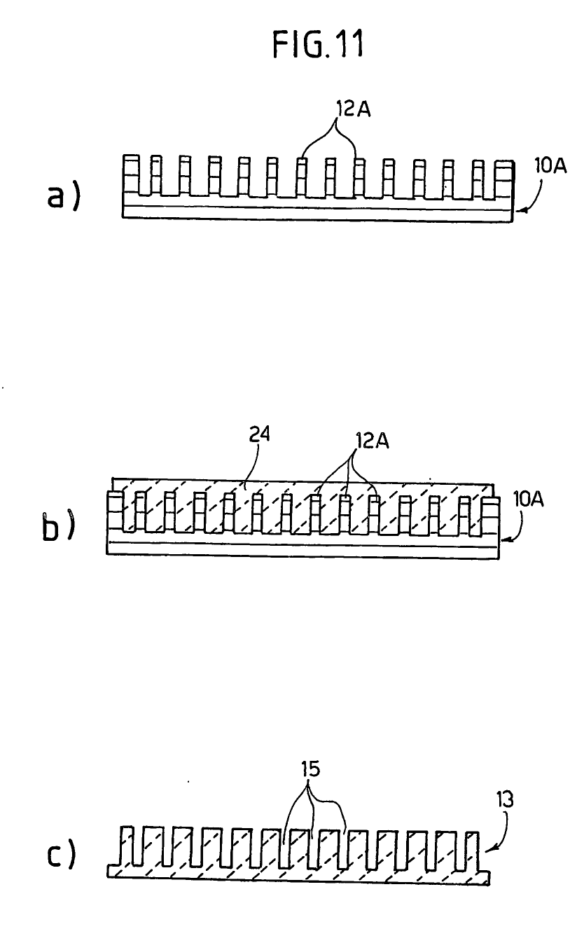

FIGS. 11, 12 and 13 are schematic sections showing three different possible implementations of the process according to the invention, as can be used to make a nano-structured component of the type shown in FIG. 7;

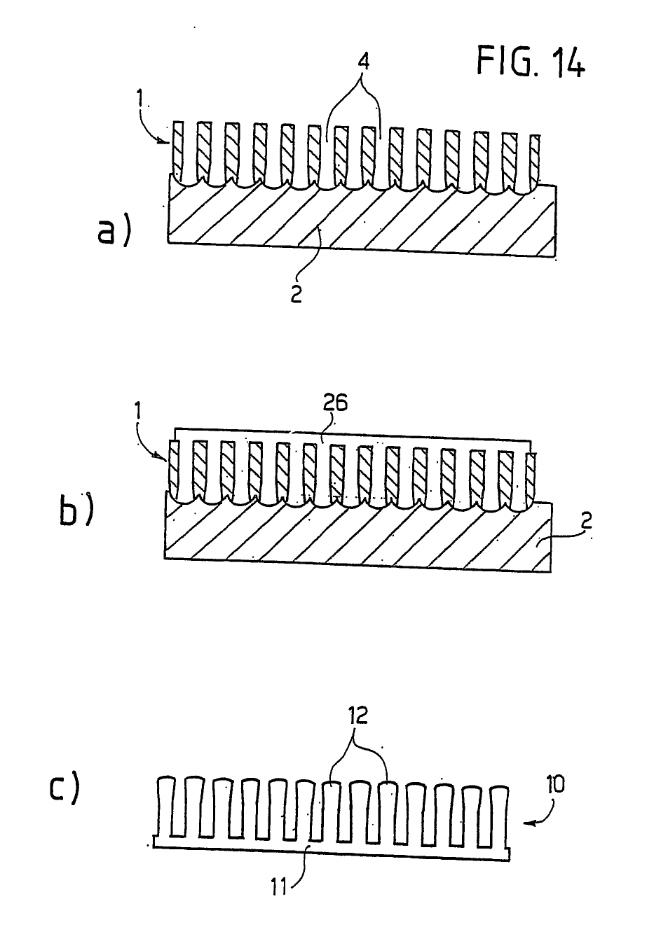

FIG. 14 shows schematic sections of a further possible implementation of the process according to the invention, as can be used to make a nano-structured component of the type shown in FIG. 6;

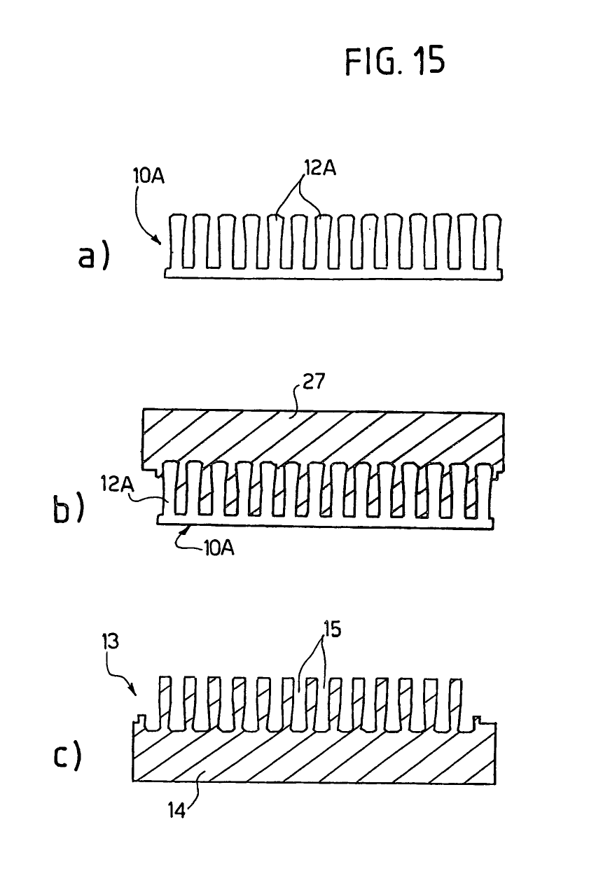

FIG. 15 shows schematic sections of a further possible implementation of the process according to the invention, as can be used to make a nano-structured component of the type shown in FIG. 7;

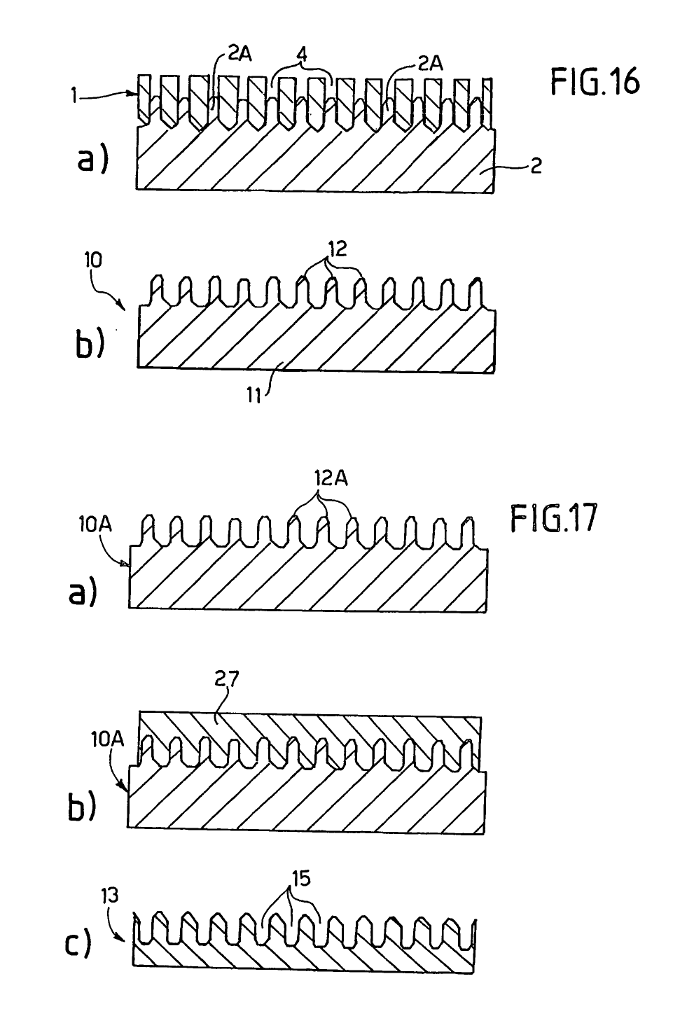

FIG. 16 shows schematic sections of a further possible implementation of the process according to the invention, as can be used to make a nano-structured component of the type shown in FIG. 6;

FIG. 17 shows schematic sections of a further possible implementation of the process according to the invention, as can be used to make a nano-structured component of the type shown in FIG. 7;

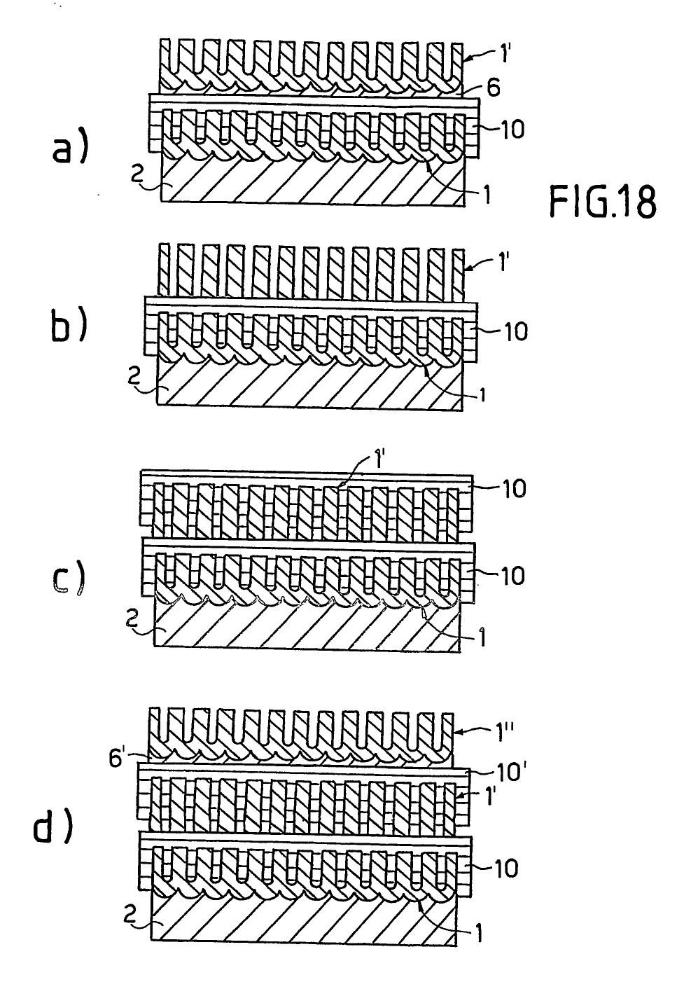

FIG. 18 shows schematic sections of a further possible implementation of the process according to the invention, as can be used to make a nano-structured component shaped as a three-dimension photonic crystal;

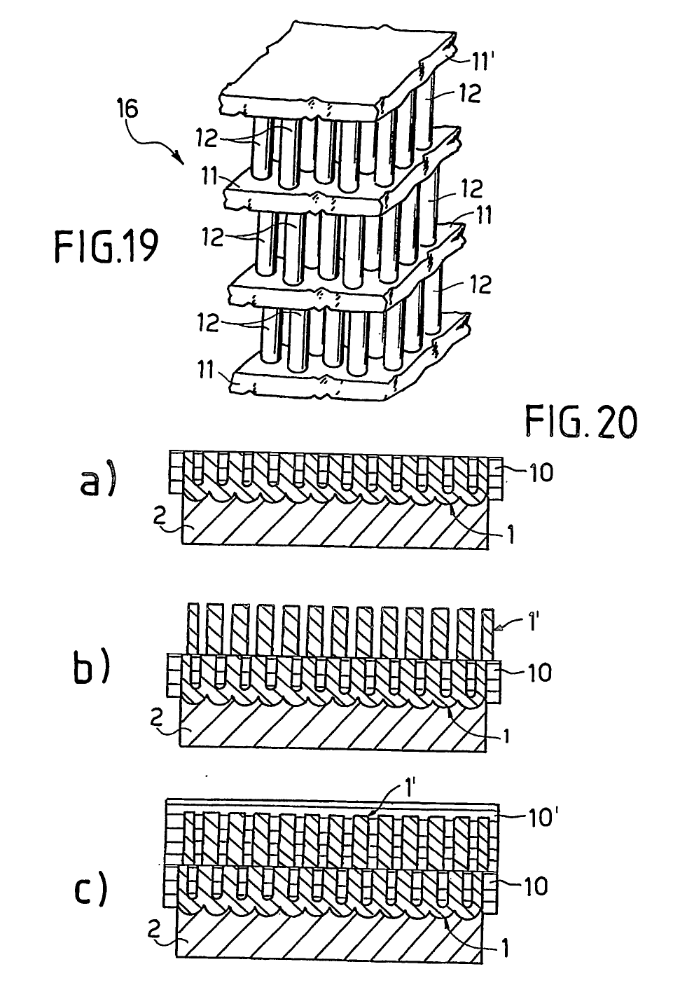

FIG. 19 is a schematic perspective view of a portion of a three-dimension photonic crystal as can be made by using the process of FIG. 18;

FIG. 20 shows schematic sections of a further possible implementation of the process according to the invention, as can be used to make a nano-structured component shaped as a three-dimension photonic crystal.

In all its possible implementations, the process according to the present invention envisages the use of at least one highly regular film made of anodized porous alumina as sacrificial element or template; depending on the case, one or more alumina layers are used directly to obtain the desired nano-structured component, or indirectly to make a further sacrificial element required to obtain the aforesaid component.

Porous alumina films have attracted attention in the past for applications such as dielectric films in aluminum capacitors, films for the retention of organic coatings and for the protection of aluminum substrates.

The structure of porous alumina can be ideally schematized as a network of hollow columns immersed in an alumina matrix. Porous alumina can be obtained by anodization of highly pure aluminum sheets or of aluminum films on substrates like glass, quartz, silicon, tungsten, and so on.

FIG. 1 shows by mere way of example a portion of a porous alumina film, globally referred to with number 1, obtained by anodic oxidation of an aluminum film on a convenient substrate, the latter being referred to with number 2. As can be seen, the alumina layer 1 comprises a series of basically hexagonal cells 3 directly close to one another, each having a straight central hole forming a pore 4, basically perpendicular to the surface of the substrate 2. The end of each cell 3 placed on the substrate 2 has a closing portion with basically hemispheric shape, all closing portions building together a non-porous part of the film 1, or barrier layer, referred to with number 5.

As is known from the prior art, the film 1 can be developed with a controlled morphology by suitably selecting the electrolyte and process physical and electrochemical parameters: in acid electrolytes (such as phosphoric acid, oxalic acid and sulfuric acid) and under suitable process conditions (voltage, current, stirring and temperature), highly regular porous films can be obtained. To said purpose the size and density of cells 3, the diameter of pores 4 and the height of film 1 can be varied; for instance the diameter of pores 4, which is typically of 50-500 nm, can be increased or decreased through chemical treatments.

As schematically shown in FIG. 2, the first step when making a porous alumina film 1 is the deposition of an aluminum layer 6 onto the substrate 2, the latter being for instance made of silicon or tungsten. Said operation requires a deposit of highly pure materials with thicknesses of one micron to 30 microns. Preferred deposition techniques for the layer 3 are thermal evaporation via e-beam and sputtering.

The step including the deposition of the aluminum layer 6 is followed by a step in which said layer is anodized. The anodization process of the layer 6 can be carried out by using different electrolytic solutions depending on the desired size and distance of pores 4.

Should the electrolyte be the same, concentration, current density and temperature are the parameters that greater affect the size of pores 4. The configuration of the electrolytic cell is also important in order to obtain a correct distribution of the shape lines of the electric field with a corresponding uniformity of the anodic process.

FIG. 3 schematically shows the result of the first anodization of the aluminum layer 6 onto the substrate 2; as schematically pointed out, the alumina film 1A obtained through the first anodization of the layer 6 does not enable to obtain a regular structure. In order to obtain a highly regular structure, such as the one referred to with number 1 in FIG. 1, it is thus necessary to carry out consecutive anodization processes, and in particular at least

i) a first anodization process, whose result can be seen in FIG. 3;

ii) a reduction step through etching of the irregular alumina film 6, carried out by means of acid solutions (for instance CrO₃ and H₃PO₄); FIG. 4 schematically shows the substrate 2 after said etching step;

iii) a second anodization of the part of alumina film 1A that has not been removed through etching.

The etching step referred to in ii) is important so as to define on the residual alumina part 1A preferential areas for alumina growth in the second anodization step.

By performing several times the consecutive operations involving etching and anodization, the structure improves until it becomes uniform, as schematically shown in FIG. 5, where the alumina film referred to with number 1 is now regular.

As shall be seen below, in some implementations of the process according to the invention, after obtaining the regular porous alumina film 1, a step involving a total or local removal of the barrier layer 5 is carried out. The barrier layer 5 insulates the alumina structure and protects the underlying substrate 2: the reduction of said layer 5 is therefore fundamental so as to perform, if necessary, consecutive electrodeposition processes requiring an electric contact, and etching processes, in case three-dimension nano-structures should be obtained directly on the substrate 2.

The aforesaid process involving the removal or reduction of the barrier layer 5 can include two consecutive stages:

widening of pores 4, performed in the same electrolyte as in previous anodization, without passage of current;

reduction of the barrier layer 5, performed by passage of very low current in the same electrolyte as in previous anodization; at this stage the typical balance of anodization is not achieved, thus favoring etching process with respect to alumina-building process.

As mentioned above, according to the invention the alumina film 1 generated through the process previously described is used as template for nano-structuring, i.e. as a base to make structures reproducing the same pattern of alumina. As shall be seen, depending on the selected implementation, it is thus possible to make negative nano-structures, i.e. basically complementary to alumina and therefore having columns on the pores of the film 1, or positive nano-structures, i.e. basically identical to alumina and therefore with cavities on the pores 4 of the film 1.

FIGS. 6 and 7 show in a partial and schematic way two nano-structured components, such as, for example, filaments for incandescence light sources, having the two types of structures referred to above, which can be carried out according to the invention; the component referred to with number 10 in FIG. 6 has the aforesaid negative structure, characterized by a base portion 11 from which the aforesaid columns referred to with number 12 start; the component referred to with number 13 in FIG. 7 has the aforesaid positive structure, characterized by a body 14 in which the aforesaid cavities referred to with 15 are defined.

As it can be seen, the two filaments 10, 13 are structured as two-dimensional photonic crystal, i.e., having a series of reliefs 12 or cavities 15 that are periodic according to two directions being orthogonal to each other.

The techniques suggested to make structured components 10, 13 as in FIGS. 6 and 7 can be quite different, and can include in particular additive techniques (such as evaporation, sputtering, Chemical Vapor Deposition, screen printing and electro-deposition), subtractive techniques (etching) and intermediate techniques (anodization of metal underlying alumina).

To this purpose some possible implementations of the process according to the invention are now described in the following.

First Implementation

FIG. 8 schematically shows some steps of a first implementation of the process according to the invention, so as to make negative structures as the one of filament 10 in FIG. 6.

The first four steps of the process include at least a first and a second anodization of a corresponding aluminum layer on a suitable substrate, as previously described with reference to FIGS. 2-5; the substrate 2 can be for instance made of silicon and the aluminum layer for the anodization processes can be deposited by sputtering or e-beam.

After obtaining the film 1 having a regular alumina structure (as can be seen in FIG. 5), the material to be nano-structured is deposited as a film onto alumina through sputtering; thus, as shown by way of example in part a) of FIG. 8, the pores of alumina 1 are filled with the deposited material, tungsten for instance, referred to with number 20.

This is followed by the removal of alumina 1 and of its substrate 2 through etching, as shown in part b) of FIG. 8, thus obtaining the desired component or filament 10 with negative nano-structure, here made of tungsten.

Sputtering technique consists in depositing films of highly pure material 20 with a thickness of 1 to 30 micron, but does not enable to reproduce structures having a high aspect ratio in an ideal way; the implementation described above is therefore used when the diameter of alumina pores 4 is at its maximum.

Therefore, instead of sputtering, the deposition of material 20 can be performed through Chemical Vapor Deposition or CVD, which is regarded as the most suitable technique for making structures of highly pure or conveniently doped metal. The main feature of this technique is the use of a reaction chamber containing reducing gases, which enable metal penetration into the hollow pores of alumina and the deposit of a continuous layer onto the surface. This ensures a faithful reproduction of high aspect ratio structures.

Second Implementation

As for the previous case, this implementation consists in making negative structures, as the one of component or filament 10 in FIG. 6; the implementation basically includes the same initial steps as those of the first implementation, as far as the deposition of the aluminum layer 6 onto the substrate 2 (FIG. 2), a first anodization (FIG. 3) and a subsequent etching (FIG. 4) are concerned. The second anodization (FIG. 5) is here performed in order to make a film 1 of thicker porous alumina than in the first implementation.

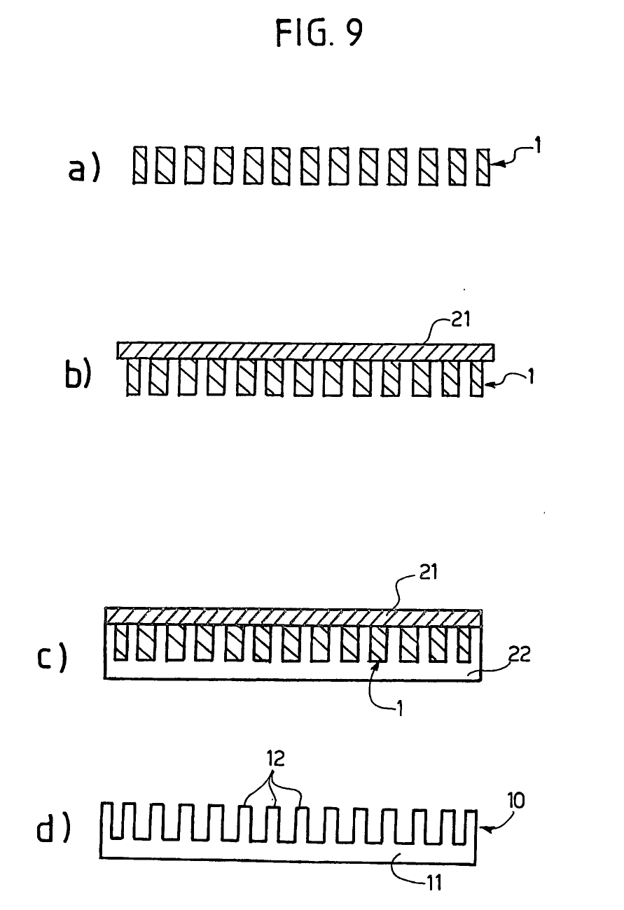

The thick alumina film 1 is then taken off its support 2 and opened at its base, so as to remove the barrier layer previously referred to with number 5, in a known way. The resulting structure of film 1 without its barrier layer can be seen in part a) of FIG. 9.

The following step, as in part b) of FIG. 9, consists in the thermal deposition, or deposition through sputtering, of a conductive metal film 21 onto alumina 1. A tungsten alloy 22 is then electrodeposited onto the structure thus obtained, as in part c) of FIG. 9, which alloy fills the pores of alumina 1. Then alumina 1 and its metal film 21 thereto associated are then removed, thus obtaining the desired nano-structured component or filament 10 made of tungsten alloy, as can be seen in part d) of FIG. 9.

Third Implementation

This implementation consists in making negative structures as the one of component or filament 10 in FIG. 6, with the same,initial steps as those in previous implementations (FIGS. 2-5).

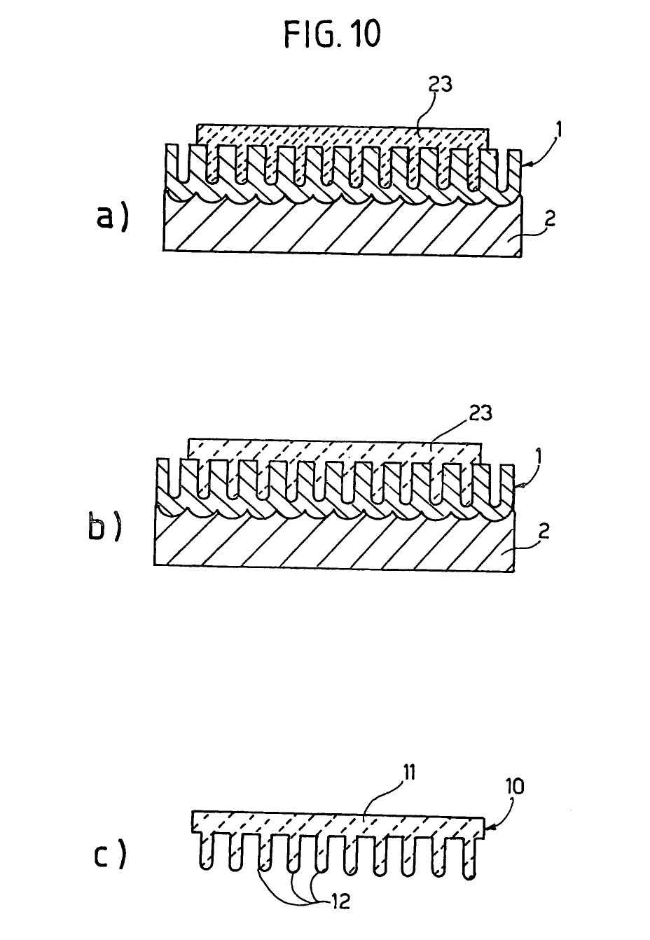

As shown in part a) of FIG. 10, the second anodization is here followed by a step in which a serigraphic paste 23 is deposited onto porous alumina 1, so as to fill its pores.

This is followed by a step in which said paste 23 is sintered, as in part b) of FIG. 10, and then alumina 1 and its substrate 2 are removed, so as to obtain the structure 10 as in part c) of FIG. 10.

This implementation enables to exploit low-cost technologies and ensures flexibility in the choice of materials. The preparation of the serigraphic paste is the first step of the process; the correct choice of the metal nano-powder, for instance comprising tungsten, solvent and binder, is fundamental to obtain a paste having ideal granulometric and rheologic properties for different types of substrates 2.

Fourth Implementation

This implementation of the process according to the invention aims at making positive structures as the one of component or filament 13 of FIG. 7, starting from a template obtained according to previous implementations.

Basically, therefore, one of previous implementations is first used to obtain a substrate having the same structure as the one of filaments previously referred to with number 10; onto said substrate, referred to with number 10A in part a) of FIG. 11, is then deposited a layer of the material 24 required to obtain the final component, for instance tungsten, through sputtering or CVD, as shown in part b) of FIG. 11; the material 24 thus covers the columns 12A of the aforesaid substrates 10A, which acts as a template.

Then the substrate 10A is taken off through selective etching, so as to obtain the component or filament 13 with positive nano-porous structure, as can be seen in part d) of FIG. 11, provided with corresponding cavities 15.

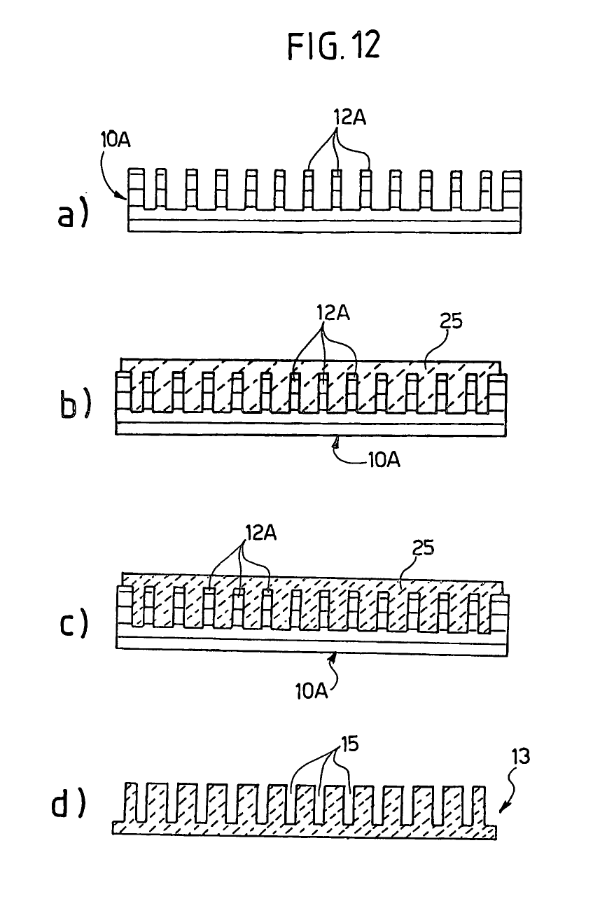

The substrate 10A, obtained according to the first three implementations described above, is not necessarily made of tungsten. In a possible variant, onto the substrate 10A, obtained as in FIGS. 8-9, a metal serigraphic paste 25 is deposited, as in parts a) and b) of FIG. 12, which is then sintered, as in part c) of FIG. 12. The substrate 10A is then taken off through selective etching, so as to obtain the filament 13 with positive nano-porous structure, as can be seen in part d) of FIG. 12.

Fifth Implementation

Also this implementation of the process according to the invention aims at carrying out positive nano-structures as the one of the component or filament previously referred to with number 13, and includes the same initial steps as those shown in FIGS. 2-5, with the deposition of an aluminum layer 6 through sputtering or e-beam onto a substrate 2 (FIG. 2), for instance made of tungsten, followed by a first anodization of aluminum 6 (FIG. 3) and an etching step (FIG. 4), so as to provide the substrate 2 with preferential areas for the growth of alumina 1 during the second anodization (FIG. 5).

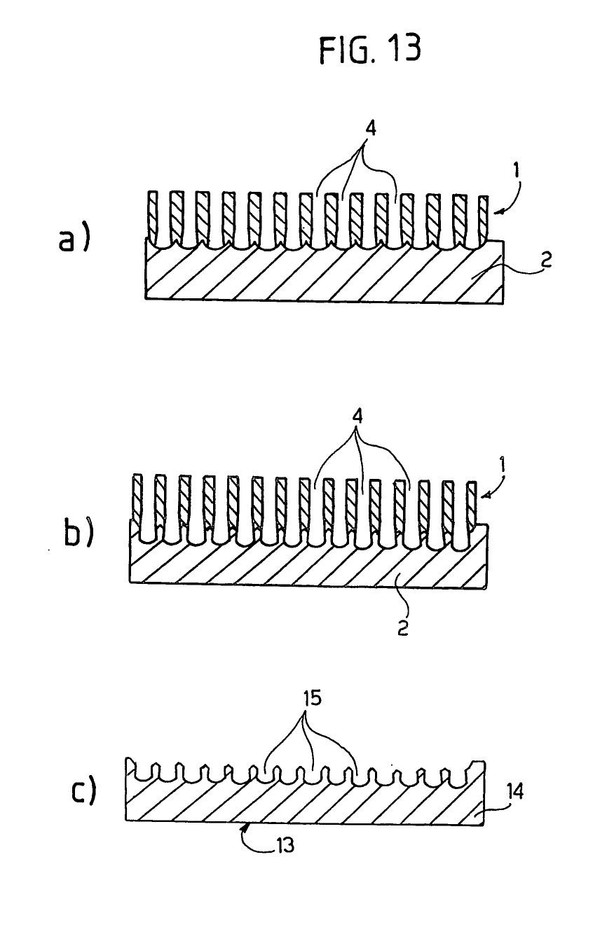

The barrier layer 5 of alumina 1 is then removed, thus opening the pores 4, as can be seen in part a) of FIG. 13. This is followed by a step of Reactive Ion Etching (RIE), which allows to “dig” selectively in the substrate 2 on the open bottom of the pores 4 of alumina 1, as can be seen in part b) of FIG. 13.

The residual alumina 1 is eventually removed, so that the tungsten substrate forms a body 14 with regular nanometric cavities 15, thus obtaining the desired filament 13.

The Reactive Ion Etching step can be replaced, if necessary, by a selective wet etching step or by an electrochemical etching step.

Sixth Implementation

This implementation of the process aims at making negative structures as the one of component or filament 10 of FIG. 6 and its initial steps are the same as in previous implementation. Therefore, after obtaining a regular film of alumina 1 on the corresponding tungsten substrate 2 (FIG. 5), the barrier layer 5 is removed, so as to open the pores 4 on the substrate 2, as can be seen in part a) of FIG. 14. This is followed by an electrochemical deposition of a tungsten alloy 26 with pulsed current, as schematically shown in part b) of FIG. 14, and eventually by the removal of residual alumina 1 and of its substrate 2, so as to obtain the desired component or filament 10, as can be seen in part c) of FIG. 14.

The sixth process first consists in preparing the concentrated electrolytic solution for tungsten deposition into the pores 4 of alumina 1; the electrolyte is very important for correctly filling the pores, since it ensures a sufficient concentration of ions in solution. The pulsed current step enables to carry out the copy of structures with high aspect ratio, and sequentially includes

i) the deposition of the tungsten alloy 26 by applying a positive current; this results in a given impoverishment of the solution close to the cathode made of alumina 1 and its substrate 2;

ii) a relax time, without current application, so as to let the solution be re-mixed close to the cathode;

iii) the application of negative current, designed to remove a part of the alloy 26 previously deposited onto the cathode, thus enabling a better leveling of deposited surface.

Steps I), ii) and iii), each lasting for a few milliseconds, are cyclically repeated until the desired structure is obtained.

Seventh Implementation

This implementation aims at making positive nano-structures as the one of component or filament 13 starting from a substrate with negative structure, obtained through previous implementation, though not necessarily made of tungsten; the aforesaid substrate with negative structure acting as template is referred to with number 10A in part a) of FIG. 15.

A tungsten layer 27 is deposited onto said substrate 10A through CVD or sputtering, as can be seen in part b) of FIG. 15. This is followed by a selective etching step, so as to remove the substrate 10A, thus obtaining the desired component or filament 13 with tungsten nano-porous structure, as can be seen in part c) of FIG. 15.

Eighth Implementation

This implementation aims at making negative nano-structures as the one of filament 10 of FIG. 6, and its initial steps are the same as those shown in FIGS. 2-5, with the deposition of an aluminum layer 6 through sputtering or e-beam onto a tungsten substrate 2 (FIG. 2), followed by a first anodization of aluminum 6 (FIG. 3) and an etching step (FIG. 4), so as to provide the substrate 2 with preferential areas for the growth of alumina 1 during the second anodization (FIG. 5).

This is followed by a step including the anodization of the tungsten substrate 2, so as to induce the localized growth of the latter, which occurs below the pores 4 of alumina 1. Said step, as shown in part a) of FIG. 16, basically includes the formation of surface reliefs 2A of the substrate 2, which first cause the barrier layer 5 of alumina 1 to break, and then keep on growing within alumina pores 4.

Through a selective etching with W/W oxide alumina 1 is then removed, so as to obtain the desired component or filament 10 with negative nano-structure as in part b) of FIG. 16.

It should be noted that this implementation is based on a typical feature of some metals, such as tungsten and tantalum, which anodize under the same chemical and electric conditions as aluminum; as mentioned above, said anodization occurs in the lower portion of the pores 4 of alumina 1, thus directly structuring the surface of the substrate 2.

Ninth Implementation

This implementation aims at carrying out positive nano-porous structures as the one of component or filament 13 of FIG. 7 starting from a substrate having a negative structure as the one obtained through previous implementation; said substrate acting as template is referred to with number 10A in part a) of FIG. 17.

A tungsten alloy 27 is deposited onto said substrate 10A through electrochemical deposition, CVD or sputtering, as shown in part b) of FIG. 17. The substrate 10A is then removed through selective etching, thus obtaining the desired filament 13 with positive or nano-porous structure.

From the above description it can be inferred that in all described implementations the process according to the invention includes the use of an alumina layer 1 which, depending on the case, directly acts as template so as to obtain the desired component with nanometric structure 10, or which is used to obtain a template 10A for the subsequent structuring of the desired component 13.

The invention proves particularly advantageous for the structuring of filaments for incandescence light sources, and more generally of components also under a different form with respect to a filament which can be led to incandescence through a passage of electric current.

The described process enables for instance to easily define, on one or more surfaces of a filament, for instance made of tungsten, an antireflection microstructure comprising a plurality of microreliefs, so as to maximize electromagnetic emission from filament into visible spectrum.

The invention can be applied advantageously to make other photon crystal structures, i.e. structures 10 made of tungsten or other suitable materials characterized by the presence of series of regular microcavities, which contain a medium with a refractive index differing from the one of tungsten or other material used.

Within this frame, it should be noticed that the previously described techniques can be advantageously used for obtaining three-dimension photonic crystals, i.e., having periodic structures along three perpendicular directions.

FIG. 18 represents, as an example, a possible technique which can be used to that purpose. Such an implementation provides for a first step similar to the one of part a) of FIG. 8. Accordingly, after a first film 1 of regular alumina has been obtained, a first layer of the material to be nano-structured, indicated with 10, is deposited onto the alumina, in order to fill the pores of the latter, as for the case shown in part a) of FIG. 8.

The filling material selected for obtaining the desired three-dimension photonic crystal can be any material (for instance, tungsten, gold, silver, carbon, iron, copper, nickel, etcetera); the technique used for material deposition can be selected from among simple or pulsed electro-deposition, thermal evaporation, electron beam, sputtering, CVD, PECVD, serigraphy, spinning, precipitation, centrifugation, sol-gel, etcetera.

On the first layer of material 10 a new film of aluminum is deposited, indicated with 6 in part a) of FIG. 18, that is then subsequently anodized in order to form a further layer of alumina, indicated with 1′; the anodizing process is carried out in such a way that the aluminum film 6, being of a suitable thickness for the purpose, is almost completely “consumed” in order to obtain the growth of the alumina layer 1′.

The barrier layer is then locally removed, or open in correspondence of the respective pore, for instance by wet etching, until the pores directly faces the underlying layer of material 10, as it is visible in part b) of FIG. 18.

A second layer of the material to be nano-structured, indicated with 10′ in part c) of FIG. 18, is then deposited on alumina 1′, for instance through electro-deposition or sputtering, in order to fill its pores, until reaching into contact with the first layer 10 of the material selected for obtaining the desired photonic crystal. On the second layer 10′, a further aluminum film is then deposited, indicated with 6′ in part d) of FIG. 18, which is subsequently anodized in order to form a further alumina layer, indicated with 1″, in the same way as previously explained in relation to layer 1′.

Again, a phase of opening or local removal of the barrier layer of alumina 1″ then follows, by wet etching, as well as the deposition of a further layer of the material aimed at forming the three-dimension photonic crystal, with such a material that can reach through the open pores of alumina 1″ into contact with the material of layer 10′.

Clearly, the above phases (aluminum deposition, alumina formation, local reduction of barrier layer, deposition of a new layer of the desired material) can be repeated for an arbitrary number of type, in function of the type of the structure to be obtained.

It is then provided an etching step of the alumina 1, 1′, 1″, . . . that has been used a nano-template and of the likely minimal aluminum residues 6, 6′, . . . ; as a consequence of said etching step, the three-dimension photonic crystal structure remains, be it final or to be completed by deposition of one or more further layers of the desired material.

To this purpose, FIG. 19 schematically represents a portion of a three-dimension photonic crystal 16, that can be obtained according to a process of the type described with reference to FIG. 18.

As it can be seen, the three-dimension photonic crystal 16 exemplified at FIG. 19 is substantially formed by a superimposition of structures of the type as shown at FIG. 6 (with the addition of an end layer 11′), and featured by a periodic series of base portion 11, that are substantially parallel and connected to each other by means of columns or pillars 12 having periodicity according to two directions being orthogonal to each other and defining therebetween respective interstices.

In case, the photonic crystal 16 can be obtained by the superimposition of a plurality of layers 10, 10′, . . . made of different materials; the various template layers 1, 1′, 1″, . . . of alumina could have periodicities, periods, filling factors also differing from each other, in the three orthogonal directions.

In the case of the implementation of FIG. 18, the various layers 10, 10′ of the material to be nano-structured comprise each a lower portion, which is provided for filling the pores of the respective film of alumina 1, 1′, 1″, and an upper portion being substantially flat, which cover on the top the same alumina.

Said planar portion could however be omitted, or anyway have such a reduced thickness (for instance 2-3 nm) so as to present discontinuities in correspondence of the upper ends of the cells of alumina.

A similar embodiment is represented in a schematic way in FIG. 20.

In this case, after a first layer of regular alumina has been obtained, a first layer of the material to be nano-structured is deposited onto the same alumina, in a way that only the pores of the latter are filled until the respective upper edge, with the upper ends of the film 1 that are not covered. Such a condition is schematically represented at part a) of FIG. 20, wherein reference 1 and 10 indicate respectively the first alumina layer and the first layer of the material to be nano-structured.

On the structure as visible at part a) of FIG. 20 a new aluminum film is then deposited, that is subsequently anodized in order to form a further film of alumina, indicated with 1′ in part b) of FIG. 20; here again the anodizing process is carried out in such a way that the aluminum layer, of a suitable thickness for the purpose, is almost completely consumed in order to obtain the growth of the film of alumina 1′. The barrier layer of alumina 1′ is then locally removed, or open in correspondence of its pores, so that the pores at least partly face the pores of the underlying alumina film 1, filled by the first layer of material 10, and the lower ends of the cells of alumina 1′ are at least in part in contact with the upper end of the cells of alumina 1.

Such a condition is schematically represented in part b) of FIG. 20.

At this point a second layer of the material to be nano-structured, indicated with 10′ in part c) of FIG. 20, is deposited on alumina 1′ (for filling only its pores, as in the previous step, or in order to form a planar surface as in the case shown in the figure), until getting into contact with the first layer 10 of the material chosen for obtaining the desired photonic crystal. On the second layer 10′ a further aluminum film can then be deposited, which is subsequently anodized in order to form a further layer of alumina, and so on until the desired structure is obtained. Also in this case a final step is provided, of etching of alumina 1, 1′ used as nano-template and of likely residues of the aluminum films.

In a further embodiment, on the nano-structured material, or between two successive layer of the material to be nano-structured, there can be provided one or more thin layer of refractory oxide. For instance, after obtaining the structure as represented in part a) of FIG. 20 (but in any case also of the structure as in part a) of FIG. 8), one or more layer of refractory oxide can be deposited on the same structure, such as a ceramic base oxide, thorium, cerium, yttrium, aluminum or zirconium oxide, or silicon carbide. On the oxide layer (or the last of the oxide layers being provided) a new film of aluminum to be anodized could be deposited, in order to form a new alumina structure to be subsequently covered with other material to be structured; on the latter, a new layer or more layers of refractory oxide will be possibly deposited, and so on until forming the desired three-dimension structure. After the final removal of alumina, the obtained structure could also be almost completely enclosed by refractory oxide; this is useful, for instance, when the desired component is an incandescence emitter, in which case the refractory oxide or oxides can perform the dual function of:

i) limiting the atomic evaporation of the material constituting the emitter, or its nano-structure, at high operating temperature, responsible for the “notching” effects of the emitter, which shorten its working life under operating conditions, and also for the nano-structure flattening effects; said evaporation, which is the greater the higher the operating temperature, would tend to flatten the superficial structure of the emitter, reducing its performance over time and its benefits in terms of efficiency increase;

ii) maintaining the morphological structure of the emitter, or of its nano-structure, even if the material which constitutes it (for instance gold, silver, copper) undergoes a state change, in particular melting, due to its use under conditions of operating temperature exceeding its melting point.

In the case of three-dimension photonic crystal, the height of the pores of the various films of alumina used for the nano-structuring could vary between 100 nm and one micron, in order to have a vertical periodicity which allows for a band gap in the visible and the near infrared.

It is finally clear to the skilled man that, in order to nano-structure three-dimension photonic crystal, the techniques previously described with reference to FIGS. 8 to 17 could be used and that, among those, different techniques could be used in combination, in order to carry out the three-dimension structuring of generic components and photonic crystals. obviously, though the basic idea of the invention remains the same, construction details and embodiments can widely vary with respect to what has been described and shown by mere way of example.

1. Process to make a nano-structured component (10; 13; 16), in particular for use in the field of photonics or the field of light emitters, the component having at least one between a series of reliefs (12) and a series of cavities or interstices (15) of nano-metric dimensions, arranged according to a substantially predefined geometry in the component (10; 13; 16), characterized in that at least one layer made of anodized porous alumina (1; 1, 1′, 1″) is used as sacrificial element for the nano-structuring of at least a part of the component (10; 13).

2. Process according to claim 1, characterized in that the alumina layer (1) is used either as sacrificial template during said nano-structuring or as intermediate template for obtaining a further sacrificial template (10A) for said nano-structuring.

3. Process according to claim 1, characterized in that, for the nano-structuring of at least a part of the component (10; 13; 16), the use of a plurality of layers of anodized porous alumina (1; 1, 1′, 1″) is provided.

4. Process according to claim 2, characterized in that each of the provided alumina layers (2) is obtained through consecutive anodizations of an aluminum film (6) deposited onto a surface of a respective substrate (2; 10, 10′), until a regular alumina structure is obtained, which defines a plurality of pores (4) substantially perpendicular to said surface of the substrate (2; 10, 10′), the alumina layer (1) having a non-porous portion (5) close to the respective substrate (2; 10, 10′).

5. Process according to claim 2, characterized in that said nano-structuring comprises a step of deposition of material through evaporation, sputtering, Chemical Vapor Deposition, serigraphy, electro-deposition, electron beam, PECVD, spinning, precipitation, centrifugation, sol-gel.

6. Process according to claim 1, characterized in that said nano-structuring comprises at leas one etching step.

7. Process according to claim 1, characterized in that said nano-structuring includes at least one step of anodization of a metal underlying a respective alumina layer (1; 1, 1′, 1″).

8. Process according to claim 2, characterized in that said nano-structuring comprises the following steps:
material (20) designed to make up at least one portion of a desired component (10; 10A) having a plurality of reliefs (12; 12A) is deposited as a film onto a respective alumina layer (1), at least a part of said material (20) filling said pores (4), and
said alumina layer (1) is then removed, at least part of said reliefs (12; 12A) being formed by the part of said material (20) which filled said pores (4).

9. Process according to claim 2, characterized in that said nano-structuring comprises the following steps:
an alumina layer (2) is formed on a conductive substrate, being of aluminum or other conductive material,
a non-porous portion (5) or barrier layer of the alumina (1) formed following the anodization is removed, namely through wet etching, such that the pores (4) of the alumina (1) result effectively open onto the conductive substrate;
a conductive metal film (21) is deposited onto the alumina layer (1), namely through electro-deposition or evaporation or sputtering techniques;
material (22) to make up at least a portion of a desired component (10; 10A) having a plurality of reliefs (12; 12A) is electro-deposited onto the structure formed by the metal film (21) and the residual part of the alumina layer (1), a part of said material (20) filling said pores (4);
the residual part of the alumina layer (1) and the metal film (21) are then removed, at least part of said reliefs (12, 12A) being formed by the part of said material (20) which filled said pores (4).

10. Process according to claim 2, characterized in that said nano-structuring comprises the following steps:
material (23) to make up at least one portion of a desired component (10; 10A) having a plurality of reliefs (12; 12A) is deposited as a serigraphic paste onto an alumina layer (1), with a part of said paste (23) that fills said pores (4),
said paste (23) is sintered, and
said alumina layer (1) and its substrate (2) are then removed, at least part of said reliefs (12; 12A) being formed by the part of said material (20) which filled said pores (4).

11. Process according to claim 2, characterized in that said nano-structuring comprises the following steps:
localized parts of a non-porous portion (5) of an alumina layer (1) are removed, so as to open said pores (4) on the respective substrate (2),
material (26) to make up at least a portion of a desired component (10; 10A) having a plurality of reliefs (12; 12A) is deposited through electrochemical methods onto the residual part of said alumina layer (1), with a part of said material (26) which fills said pores (4) and gets into contact with the respective substrate (2; 6, 6′), and
the residual part of said alumina layer (1) and the respective substrate (2) are then removed, at least part of said reliefs (12,12A) being formed by the part of said material (20) which filled said pores (4).

12. Process according to claim 2, characterized in that said nano-structuring comprises the following steps:
the substrate (2) of an alumina layer (1) undergoes anodization, so as to induce a growth of the substrate (2) below said pores (4), said growth resulting in the formation of surface projections (2A) of the substrate (2), which first cause parts of the non-porous portion (5) of said alumina layer (1) to break and then keep on growing within said pores (4), and
said alumina layer (1) is removed through selective etching, a desired component (10) having a plurality of reliefs (12) being thus at least partly made by the substrate (2), said surface projections (1A) making up said reliefs (12).

13. Process according to claim 9, characterized in that said desired component is said further template (10A).

14. Process according to claim 13, characterized in that said nano-structuring comprises the following steps:
a layer of the material (24, 25) to make up at least a portion of said component (13) is deposited onto said further template (10A), and
said further template (10A, 13A) is removed.

15. Process according to claim 14, characterized in that material (24) to make up at least a portion of said component (13) is deposited onto said further template (10A, 13A) through sputtering or Chemical Vapor Deposition, and in that said further template (10A, 13A) is removed through selective etching.

16. Process according to claim 14, characterized in that material (24, 25) to make up at least a portion of said component (13) is in the form of a serigraphic paste (25), which is sintered after being deposited onto said further template (10A, 13A), the latter being then removed through selective etching.

17. Process according to claim 2, characterized in that said nano-structuring comprises the following steps:
at least a part of a non-porous portion (5) of an alumina layer (1) is removed, said pores (4) being thus opened on the respective substrate (2),
said substrate (2) is selectively dug in the corresponding areas being open on said pores (4),
the residual part of said alumina layer (1) is removed, the substrate thus making up said component (13), the dug areas of the substrate (2) making up said cavities (15).

18. Process according to claim 17, characterized in that the substrate (2) is dug on said open areas through Reactive Ion Etching or selective wet etching or electrochemical etching.

19. Process according to claim 3, characterized in that said nano-structuring comprises
forming at least a first layer of alumina (1), onto which at least a first portion (10) of the material to make up said component (16) is deposited;
forming, on said first portion of material (10), of at least a second layer of alumina (1′), onto which at least a second portion (10) of the material to make up said component (16) is then deposited.

20. Process according to claim 19, characterized in that there is provided for at least a step of removal of said first and second layer of alumina (1, 1′), as well as of likely residues of a respective aluminum substrate (6, 6′), in particular through etching.

21. Process according to claim 1, characterized in that said nano-structuring comprises
forming at least a first layer of alumina (1), onto which at least a first portion (10) of the material to make up said component (16) is deposited;
depositing, onto said first portion of material (10), at least a layer of refractory oxide, such as a ceramic base oxide, thorium, cerium, yttrium, aluminum, or zirconium oxide, or silicon carbide.

22. Process according to claim 21, characterized in that formation is provided, on the refractory oxide, of at least a second layer of alumina (1′), onto which at least a second portion (10) of the material to make up said component (16) is then deposited.

23. Process according to claim 21, characterized in that there is provided for at least a step of removal of the layer or layers of alumina (1, 1′), as well as of likely residues of a respective aluminum substrate (6, 6′), in particular through etching, and that the thus obtained component (16) is almost completely enclosed within refractory oxide.

24. Emitter for light sources, in particular a filament, which can be led to incandescence through the passage of electric current, obtained at least partly with the process according to claim 1, the emitter (10; 13; 16) having at least one between a plurality of nano-metric reliefs (12) and a plurality of nano-metric cavities or interstices (15) arranged according to a substantially predefined geometry.

25. Emitter according to claim 24, where said reliefs (12) or cavities (15) make up an antireflection microstructure, in order to maximize electromagnetic emission from the emitter (10; 13; 16) into visible spectrum.

26. Two-dimensional photonic crystal, obtained at least partly with the process according to claim 1, the crystal (10; 13) having at least one between a plurality of nano-metric reliefs (12) and a plurality of nano-metric cavities or interstices (15) arranged according to a substantially predefined geometry.

27. Three-dimensional photonic crystal, obtained at least partly with the process according to claim 1, the crystal (16) having at least one between a plurality of nano-metric reliefs (12) and a plurality of nano-metric cavities or interstices (15) arranged according to a substantially predefined geometry.

28. Use of anodized porous alumina (1) as sacrificial element for the nano-structuring of at least a part of an emitter (10; 13) for light sources, which can be led to incandescence through the passage of electric current.

29. Use of anodized porous alumina (1) as sacrificial element for the nano-structuring of a two-dimensional or three dimensional photonic crystal (10; 13; 16).

30. Use according to claim 28, where alumina (1) is used as template during said nano-structuring.

31. Use according to claim 28, where alumina (1) is used as template for obtaining a further template (10A, 13A) used during said nano-structuring.

32. Use according to claim 28, where said nano-structuring comprises obtaining at least one between a plurality of nanometric reliefs (12) and a plurality of nanometric cavities (15) arranged according
